(19) United States
(12) Patent Application Publication
(10) Pub. No.: US 2018/0228023 A1
(43) Pub. Date: Aug. 9, 2018

(54) ANGLED FIBERGLASS CLOTH WEAVES

(71) Applicant: International Business Machines Corporation, ARMONK, NY (US)

(72) Inventors: MICHAEL A. CHRISTO, ROUND ROCK, TX (US); JOSE A. HEJASE, AUSTIN, TX (US); ROGER S. KRABBENHOFT, ROCHESTER, MN (US); DIANA D. ZUROVETZ, ROUND ROCK, TX (US)

(21) Appl. No.: 15/428,688

(22) Filed: Feb. 9, 2017

(51) Int. Cl. H05K 1/03; H05K 1/02; H05K 3/00; D03D 1/00; D03D 15/00

(52) U.S. Cl. CPC H05K 1/0306; H05K 1/038; H05K 1/0245; H05K 2201/029; D03D 1/0088; D03D 15/0011; H05K 2201/0206; H05K 3/0044

(57) ABSTRACT

A process of forming an angled fiberglass cloth weave includes weaving a first set of fibers oriented at a first non-orthogonal angle with respect to a printed circuit board to be formed from the angled fiberglass cloth weave with a second set of fibers oriented at a second non-orthogonal angle with respect to the printed circuit board to be formed form the angled fiberglass cloth weave.

### BACKGROUND

High speed nets routed over an orthogonal weave create signal integrity issues due to signal skew within differential pairs. Angled routing of nets with respect to printed circuit board (PCB) edges can address differential in-pair skew issues but may place restrictions on physical design that may prohibit its use. Other routing schemes (such as “zig-zag” routing schemes) may also be associated with prohibitive physical design restrictions. Alternatively, the PCB image can be rotated within the manufacturing panel to address differential in-pair skew issues but may result in reduced panel efficiency and a substantial cost increase.

### SUMMARY

According to an embodiment, a process of forming an angled fiberglass cloth weave is disclosed. The process includes weaving a first set of fibers oriented at a first non-orthogonal angle with respect to a printed circuit board to be formed from the angled fiberglass cloth weave with a second set of fibers oriented at a second non-orthogonal angle with respect to the printed circuit board to be formed form the angled fiberglass cloth weave.

According to another embodiment, an article of manufacture that includes an angled fiberglass cloth weave is disclosed. The angled fiberglass cloth weave is formed by a process comprising weaving a first set of fibers oriented at a first non-orthogonal angle with respect to a printed circuit board to be formed from the angled fiberglass cloth weave with a second set of fibers oriented at a second non-orthogonal angle with respect to the printed circuit board to be formed form the angled fiberglass cloth weave.

According to another embodiment, a process of forming a printed circuit board is disclosed. The process includes forming a pre-impregnated material from an angled fiberglass cloth weave and a resin material. The angled fiberglass cloth weave has a first set of fibers oriented at a first non-orthogonal angle with respect to a printed circuit board to be formed from the pre-impregnated material and a second set of fibers oriented at a second non-orthogonal angle with respect to the printed circuit board. The process also includes utilizing the pre-impregnated material to form the printed circuit board. The process further includes forming a set of differential pairs on the printed circuit board. A first trace of the set of differential pairs and a second trace of the set of differential pairs each encounter the same effective dielectric constant along a total trace length.

The foregoing and other objects, features, and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 is a diagram depicting a process of forming an angled fiberglass cloth weave for use in printed circuit board manufacturing, according to one embodiment.

FIG. 2 is a diagram illustrating an exploded view of a differential pair formed on a printed circuit board that is formed from the angled fiberglass cloth weave, where each trace of the differential pair encounters the same effective dielectric constant along a total length of the trace, according to one embodiment.

FIG. 3 is a flow diagram depicting a particular embodiment of a process of forming an angled fiberglass cloth weave and utilizing the angled fiberglass cloth weave to form a printed circuit board having a differential pair where each trace of the differential pair encounters the same effective dielectric constant along a total length of the trace.

### DETAILED DESCRIPTION

The present disclosure describes systems and methods of forming angled fiberglass cloth weaves for printed circuit boards. As described further herein, weaving the fiberglass cloth at an angle other than 0 and 90 degrees may allow for conventional orthogonal routing of high speed nets while mitigating/eliminating signal integrity issues associated with conventional woven fiberglass cloths.

A high-speed bus is a communication channel that interconnects central processing units (CPUs) to other computer systems, storage systems, network switches or other peripherals. The physical implementation of a high-speed bus presents many design choices driven by technologies, cost, and reliability, among other factors. Such choices include printed circuit board designs (e.g., thickness, number of layers, and material properties), differential or single ended wiring, wiring density clearance/spacing from noise sources, types of connectors to use, via type and properties, among other choices. Requirements for high-speed bus communication include high throughput and low latency and the maintenance of signal integrity, among others. Challenges include maintaining signal amplitude and shape, minimizing dispersion, and minimizing the phase offset between traces within differential pairs, among others.

A particular challenge in high-speed bus communications is the differential-pair stripline, which represents the basic unit structure for a transmission line/interconnect. In the differential-pair stripline, a signal flows through the coupled lines in a differential mode for noise cancellation, among other benefits. One challenge associated with the differential-pair stripline is maintaining uniform stripline impedance throughout the length of the pair. When the propagation velocity differs in the traces which compromise a differential pair, there is a difference in delay between the two traces, also referred to as skew. These differences result in a degradation in the quality of the signal at the point where it is received. While there are numerous factors that contribute to skew, in-homogeneities in the dielectric material of a printed circuit board laminate structure represents one cause of skew. The present disclosure describes an angled fiberglass cloth weave to mitigate glass weave skew effects.

Glass weaves are bound together, surrounded and impregnated by resins. Electrical properties, particularly the dielectric constant (εᵣ) of these materials are different. Hence, there is variation of the effective dielectric constant (ε_{eff}) in the PCB laminate structure. The variation of the effective dielectric constant leads to variations of impedance of the strip-lines in addition to different propagation delays on the nets of differential pairs if they are consistently routed within different effective dielectric constant regions. The effective dielectric constant is a function of the dielectric constant of the glass (ε_{glass}), the dielectric constant of the resin (εᵣₑₛᵢₙ), and the percentage volume of glass and resin in the laminate layers which comprise the printed circuit board. Ultimately, this leads to skew in differential pairs and data transmission errors. Additionally, impedance variations along a stripline can lead to unwanted reflections lowering amplitude. These variations depend on the weave structure, the position of traces with respect to weaves, trace dimensions, etc., and are thus difficult to control.

Possible solutions to mitigate glass weave skew effects include rotating a conventional orthogonal glass fabric at a slight angle relative to the differential pair. One shortcoming of this approach is the potential cost increase associated with material waste driven by rotating the glass cloth relative to a rectangular PCB panel and cutting the glass cloth, in addition to the cost of additional manufacturing steps. Another approach includes slight angle rotation of the differential pair relative to the glass cloth. A shortcoming of this approach is that there may be a physical design implementation challenge in the case of tight board spaces and time requirements. Yet another approach includes matching dielectric constants of glass cloth and resin. A shortcoming of this approach is that there may be a significant cost increase to a PCB build.

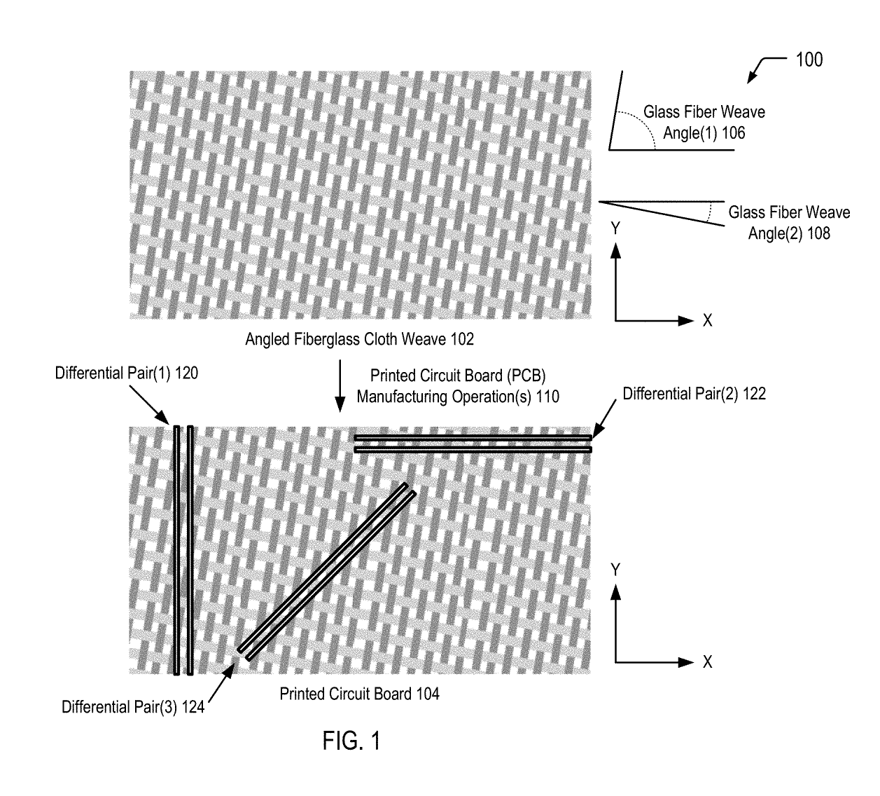

Referring to FIG. 1, a diagram 100 depicts an example of an angled fiberglass cloth weave 102 for manufacturing of a printed circuit board 104, according to one embodiment. FIG. 1 illustrates that, during a glass fiber weaving operation to form the angled fiberglass cloth weave 102, a first set of glass fibers oriented at a first angle 106 (identified as “Glass Fiber Weave Angle(1)” in FIG. 1) are interwoven with a second set of glass fibers oriented at a second angle 108 (identified as “Glass Fiber Weave Angle(2)” in FIG. 1). In the example of FIG. 1, the first angle 106 may be defined with respect to the X-axis of a rectangular printed circuit board formed using the angled fiberglass cloth weave 102, and the second angle 108 may be defined with respect to the Y-axis of the rectangular printed circuit board.

In FIG. 1, after formation of the angled fiberglass cloth weave 102, one or more printed circuit board (PCB) manufacturing operations 110 may be performed. For example, while not shown in FIG. 1, the PCB manufacturing operation(s) 110 may include forming a PCB laminate structure using multiple layers of the angled fiberglass cloth weave 102 impregnated with a resin material. FIG. 1 further illustrates that a set of differential pairs may be formed on the printed circuit board 104 that is formed from the angled fiberglass cloth weave 102. In the particular embodiment depicted in FIG. 1, the set of differential pairs includes a first differential pair 120 (identified as “Differential Pair(1)” in FIG. 1), a second differential pair 122 (identified as “Differential Pair(2)” in FIG. 1), and a third differential pair 124 (identified as “Differential Pair(3)” in FIG. 1). It will be appreciated that the printed circuit board 104 may include alternative numbers and/or arrangements of differential pairs.

In the particular embodiment depicted in FIG. 1, the first differential pair 120 is oriented at an angle of about 90 degrees with respect to the X-axis of the printed circuit board 104, the second differential pair 122 is oriented at an angle of about 0 degrees with respect to the X-axis of the printed circuit board 104, and the third differential pair 124 is oriented an angle of about 45 degrees with respect to the X-axis of the printed circuit board 104. It will be appreciated that the example of FIG. 1 represents an illustrative, non-limiting example of a wiring scheme and that various alternative numbers and/or arrangements of differential pairs may be disposed on a printed circuit board formed from the angled fiberglass cloth weave 102 of FIG. 1 as long as the differential pairs are not routed with same angle as the glass weave bundles or parallel to them.

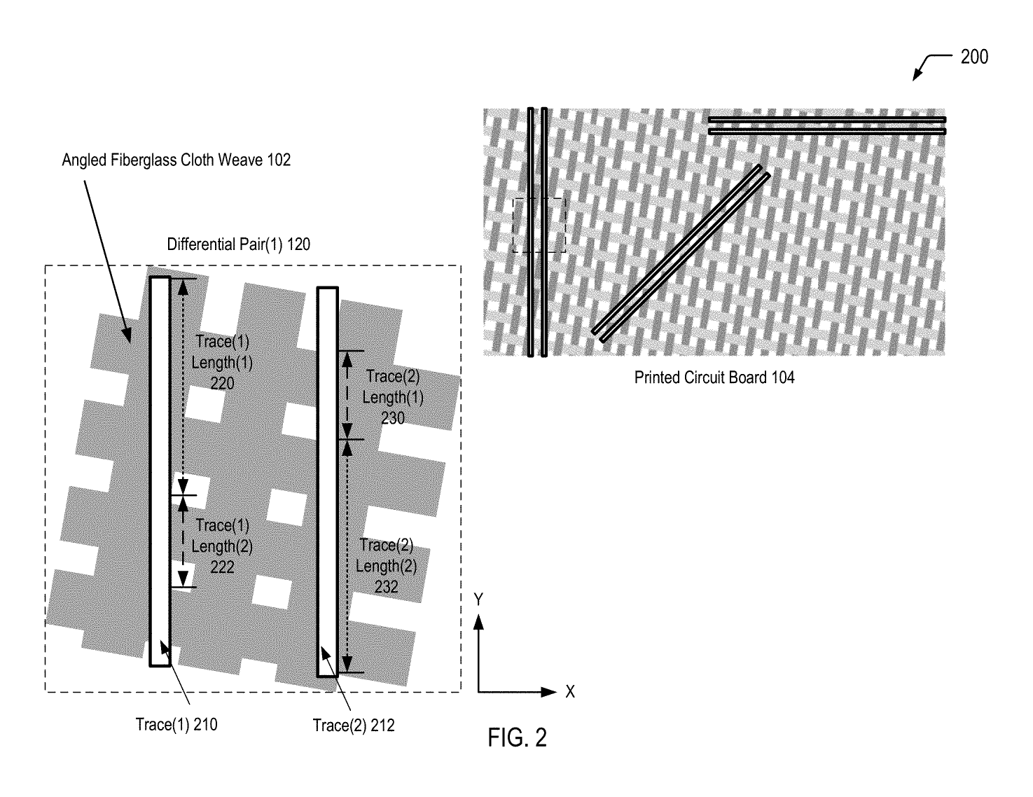

As described further herein with respect to FIG. 2, the angled fiberglass cloth weave 102 of FIG. 1 may be utilized to maintain a substantially uniform stripline impedance throughout the length of a differential pair, thereby mitigating skew associated with in-homogeneities associated with woven fiberglass cloths.

Thus, FIG. 1 illustrates an example of an angled fiberglass cloth weave that may be used to mitigate/eliminate signal integrity issues associated with conventional woven fiberglass cloths. In contrast to a glass weave skew mitigation strategy that relies on rotation of a conventional orthogonal glass cloth, weaving the glass fibers at an angle during glass cloth formation does not result in price increases associated with rotating/cutting the glass cloth relative to a rectangular PCB panel and the additional manufacturing steps. Further, in contrast to a glass weave skew mitigation strategy that relies on angular rotation of the differential pair relative to the glass cloth, weaving the glass fibers at an angle during glass cloth formation eliminates potential physical design implementation challenge in the case of tight board spaces and time requirements. Additionally, weaving the glass fibers at an angle during glass cloth formation does not require matching of dielectric constants of glass cloth and resin that may be associated with a significant cost increase to a PCB build.

Referring to FIG. 2, a diagram 200 illustrates an exploded view of a portion of the first differential pair 120 of the printed circuit board 104 formed from the angled fiberglass cloth weave 102 of FIG. 1. It will be appreciated that the advantages described herein with respect to the first differential pair 120 also apply to the other differential pairs 122, 124 that are oriented at different angles with respect to the printed circuit board 104. In each case, the angled fiberglass cloth weave 102 of FIG. 1 may be utilized to maintain a substantially uniform stripline impedance throughout the length of a differential pair, thereby mitigating skew associated with in-homogeneities associated with conventional orthogonal woven fiberglass cloths.

As previously described herein with respect to FIG. 1, the exploded view of FIG. 2 illustrates that the first differential pair 120 is oriented at an angle of about 90 degrees with respect to the X-axis of the printed circuit board 104. FIG. 2 illustrates that a first signal trace 210 of the first differential pair 120 (identified as “Trace(1)” in FIG. 2) encounters a first set of variable dielectric constants along its length, and a second signal trace 212 of the first differential pair 120 (identified as “Trace(2)” in FIG. 2) encounters a second set of variable dielectric constants along its length. While the first set of variable dielectric constants may differ from the second set of dielectric constants, FIG. 2 illustrates that the first set of variable dielectric constants and the second set of variable dielectric constants may be correspond to the same effective dielectric constant along the length of the signal traces 210, 212.

In FIG. 2, a signal along the first trace 210 may encounter one dielectric constant along a first length 220 (depicted as “Trace(1) Length(1)” in FIG. 2) and may encounter a different dielectric constant along a second length 222 (depicted as “Trace(1″) Length(2)” in FIG. 2). A signal along the second trace 212 may encounter one dielectric constant along a first length 230 (depicted as “Trace(2) Length(1)” in FIG. 2) and may encounter a different dielectric constant along a second length 232 (depicted as “Trace(2″) Length(2)” in FIG. 2).

In the example of FIG. 2, the first length 220 of the first trace 210 may correspond to a portion of the first trace 210 that overlies a continuous segment of a glass fiber of the angled fiberglass cloth weave 102, while the second length 222 of the first trace 210 may correspond to another portion of the first trace 210 that at least partially overlies a discontinuity in the angled fiberglass cloth weave 102. Accordingly, a first dielectric constant (ε₁) may be associated with the first length 220 of the first trace 210, and a second dielectric constant (ε₂) may be associated with the second length 222 of the first trace 210. The effective dielectric constant (ε_{eff}) encountered along a total length of the first trace 210 may be determined as a function of the first dielectric constant (ε₁) along the first length 220 and the second dielectric constant (ε₂) along the second length 222.

In contrast to the first trace 210, FIG. 2 illustrates that the first length 230 of the second trace 212 may correspond to a portion of the second trace 212 that at least partially overlies a discontinuity in the angled fiberglass cloth weave 102, and the second length 232 of the second trace 212 may correspond to another portion of the second trace 212 that overlies a continuous segment of a glass fiber of the angled fiberglass cloth weave 102. Accordingly, one dielectric constant may be associated with the first length 230 of the second trace 212, and a different dielectric constant may be associated with the second length 232 of the second trace 212. The dielectric constant associated with the first length 230 of the second trace 212 may correspond to the second dielectric constant (ε₂) along the second length 222 of the first trace 210 (that also overlies a fiber discontinuity). The dielectric constant associated with the second length 232 of the second trace 212 may correspond to the first dielectric constant (ε₁) along the first length 220 of the first trace 210 (that also overlies a continuous glass fiber segment of the angled fiberglass cloth weave 102). As such, an effective dielectric constant encountered along a total length of the second trace 212 may be the same as the effective dielectric constant (ε_{eff}) encountered along the total length of the first trace 210.

Thus, FIG. 2 illustrates that the angled fiberglass cloth weave 102 of FIG. 1 may be utilized to maintain a substantially uniform stripline impedance throughout the length of a differential pair, thereby mitigating skew associated with in-homogeneities in conventional orthogonal woven fiberglass cloths. While each trace of a differential pair may encounter a different sequence of materials with different dielectric constants at a particular location with respect to the underlying angled fiberglass cloth weave, each trace may encounter the same effective dielectric constant when calculated along the total length.

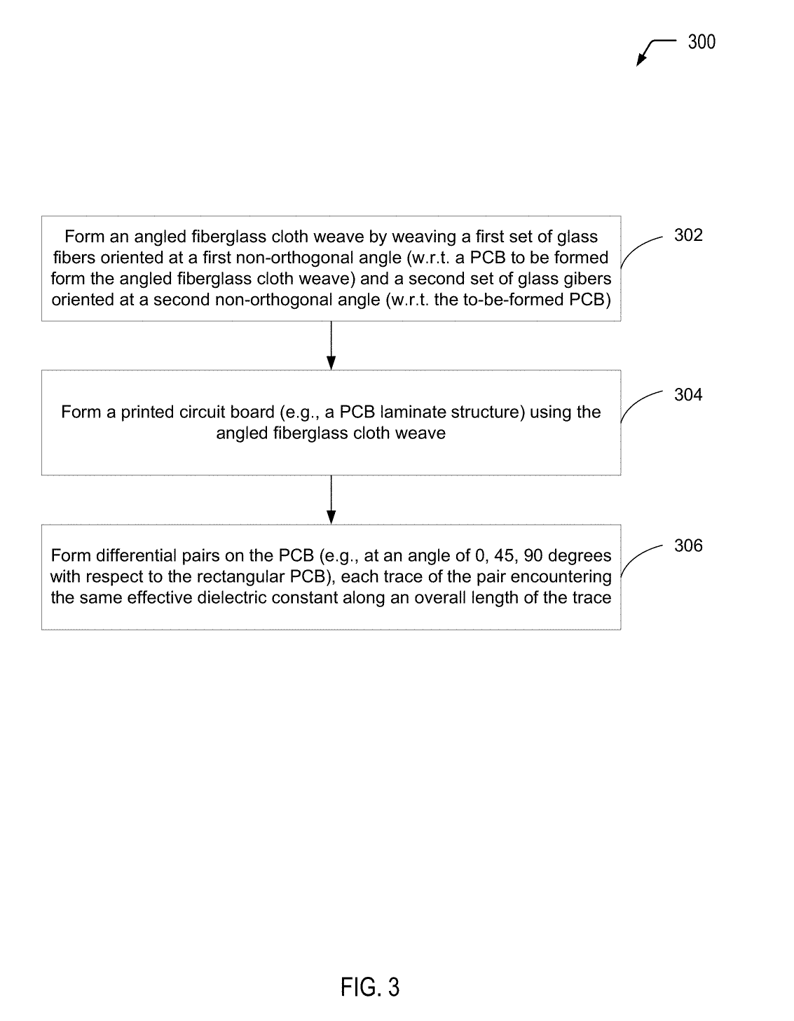

Referring to FIG. 3, a flow diagram illustrates an example of a process 300 of forming an angled fiberglass cloth weave for printed circuit board manufacturing, according to one embodiment. In the particular embodiment depicted in FIG. 3, the process 300 also includes forming a printed circuit board using the angled fiberglass cloth weave as well as forming differential pairs on the printed circuit board. It will be appreciated that the operations shown in FIG. 3 are for illustrative purposes only and that the operations may be performed in alternative orders, at alternative times, by a single entity or by multiple entities, or a combination thereof. As an example, one entity may form the angled fiberglass cloth by weaving glass fibers at an angle during manufacturing, while another entity may form the printed circuit board (e.g., a PCB laminate) using the angled fiberglass cloth weave, and other entity may form differential pairs on the printed circuit board.

The process 300 includes forming an angled fiberglass cloth weave by weaving glass fibers at an angle during manufacturing, at 302. Weaving the glass fibers at an angle during manufacturing includes weaving a first set of fibers oriented at a first non-orthogonal angle (with respect to a printed circuit board to be formed from the angled fiberglass cloth weave) with a second set of fibers oriented at a second non-orthogonal angle with respect to the to-be-formed PCB. For example, referring to FIG. 1, the angled fiberglass cloth weave 102 may be formed by weaving a first set of glass fibers at the first glass fiber weave angle 106 with a second set of glass fibers at the second glass fiber weave angle 108. As previously described herein, the first glass fiber weave angle 106 and the second glass fiber weave angle 108 may be described with respect to an X-Y axis of a rectangular PCB that is subsequently formed using the angled fiberglass cloth weave 102.

In the particular embodiment illustrated in FIG. 3, the process 300 also includes forming a printed circuit board using the angled fiberglass cloth weave, at 304. For example, the printed circuit board may correspond to the printed circuit board 104 depicted in FIGS. 1 and 2. As previously described herein, the printed circuit board 104 may include a PCB laminate structure that is formed from multiple layers of the angled fiberglass cloth weave 102 impregnated with a resin material.

In the particular embodiment depicted in FIG. 3, the process 300 further includes forming differential pairs on the PCB, at 306. Each trace of the pair encounters the same effective dielectric constant along an overall length of the trace. For example, referring to FIG. 1, the first differential pair 120 is oriented at an angle of substantially 90 degrees with respect to the X axis of the rectangular printed circuit board 104, the second differential pair 122 is oriented at an angle of substantially 0 degrees with respect to the rectangular printed circuit board 104, and the third differential pair 124 is oriented at an angle of substantially 45 degrees with respect to the printed circuit board 104. As described further herein with respect to FIG. 2, each trace of a particular differential pair (e.g., the two traces 210, 212 of the first differential pair 120) encounters the same effective dielectric constant along a total trace length. While FIG. 2 illustrates the example of the first differential pair 120 in detail, each of the traces of the other differential pairs 122 and 124 depicted in FIG. 1 may also experience the same effective dielectric constant along a total trace length.

Thus, FIG. 3 illustrates an example of a process of forming an angled fiberglass cloth weave and utilizing the angled fiberglass cloth weave to mitigate/eliminate signal integrity issues associated with conventional woven fiberglass cloths. In contrast to a glass weave skew mitigation strategy that relies on rotation of a conventional orthogonal glass cloth, weaving the glass fibers at an angle during glass cloth formation does not result in price increases associated with rotating/cutting the glass cloth relative to a rectangular PCB panel and the additional manufacturing steps. Further, in contrast to a glass weave skew mitigation strategy that relies on angular rotation of the differential pair relative to the glass cloth, weaving the glass fibers at an angle during glass cloth formation eliminates potential physical design implementation challenge in the case of tight board spaces and time requirements. Additionally, weaving the glass fibers at an angle during glass cloth formation does not require matching of dielectric constants of glass cloth and resin that may be associated with a significant cost increase to a PCB build.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

1. A process of forming an angled fiberglass cloth weave, the process comprising weaving a first set of fibers oriented at a first non-orthogonal angle with respect to a printed circuit board to be formed from the angled fiberglass cloth weave with a second set of fibers oriented at a second non-orthogonal angle with respect to the printed circuit board to be formed form the angled fiberglass cloth weave.

2. The process of claim 1, further comprising utilizing the angled fiberglass cloth weave to form the printed circuit board.

3. The process of claim 2, wherein the printed circuit board includes a printed circuit board laminate structure that is formed from multiple layers of the angled fiberglass cloth weave impregnated with a resin material.

4. The process of claim 2, further comprising forming a set of differential pairs on the printed circuit board.

5. The process of claim 4, wherein the set of differential pairs includes a differential pair having traces oriented at substantially ninety degrees with respect to a rectangular surface of the printed circuit board.

6. The process of claim 4, wherein the set of differential pairs includes a differential pair having traces oriented at substantially zero degrees with respect to a rectangular surface of the printed circuit board.

7. The process of claim 4, wherein the set of differential pairs includes a differential pair having traces oriented at substantially forty five degrees with respect to a rectangular surface of the printed circuit board.

8. The process of claim 4, wherein a first trace of the set of differential pairs and a second trace of the set of differential pairs each encounter the same effective dielectric constant along a total trace length.

9. An article of manufacture including an angled fiberglass cloth weave, the angled fiberglass cloth weave formed by a process comprising weaving a first set of fibers oriented at a first non-orthogonal angle with respect to a printed circuit board to be formed from the angled fiberglass cloth weave with a second set of fibers oriented at a second non-orthogonal angle with respect to the printed circuit board to be formed form the angled fiberglass cloth weave.

10. The article of manufacture of claim 9, wherein the article of manufacture includes a pre-impregnated material that includes the angled fiberglass cloth weave impregnated with a resin material.

11. The article of manufacture of claim 9, wherein the article of manufacture includes a printed circuit board that includes the angled fiberglass cloth weave, the process further comprising utilizing the angled fiberglass cloth weave to form the printed circuit board.

12. The article of manufacture of claim 11, wherein the printed circuit board includes a printed circuit board laminate structure that is formed from multiple layers of the angled fiberglass cloth weave impregnated with a resin material.

13. The article of manufacture of claim 11, wherein the printed circuit board includes a set of differential pairs.

14. The article of manufacture of claim 13, wherein the set of differential pairs includes a differential pair having traces oriented at substantially ninety degrees with respect to a rectangular surface of the printed circuit board.

15. The article of manufacture of claim 13, wherein the set of differential pairs includes a differential pair having traces oriented at substantially zero degrees with respect to a rectangular surface of the printed circuit board.

16. The article of manufacture of claim 13, wherein the set of differential pairs includes a differential pair having traces oriented at substantially forty five degrees with respect to a rectangular surface of the printed circuit board.

17. The article of manufacture of claim 13, wherein a first trace of the set of differential pairs and a second trace of the set of differential pairs each encounter the same effective dielectric constant along a total trace length.

18.-20. (canceled)
